(19) United States
(12) Patent Application Publication
(10) Pub. No.: US 2002/0166696 A1
(43) Pub. Date: Nov. 14, 2002

(54) Land grid array (LGA) pad repair structure and method

(75) Inventors: Bruce J. Chamberlin, Vestal, NY (US); Mark Kenneth Hoffmeyer, Rochester, MN (US); Wai Mon Ma, Poughkeepsie, NY (US); Arch F. Nuttall III, Hyde Park, NY (US); James R. Stack, Endicott, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY

(21) Appl. No.: 09/852,998

(22) Filed: May 10, 2001

(51) Int. Cl. H05K 3/22; H05K 3/24

(52) U.S. Cl. 174/262; 174/250; 174/266; 29/850; 29/847

(57) ABSTRACT

A method and structure to repair or modify a land grid array (LGA) interface mounted on a printed circuit card. The land grid array interface has a plurality of contact pads on a first surface of the printed circuit card, each contact pad is connected to at least one electronic component by a conductor. The method includes, for a preselected one of the contact pads to be replaced, drilling a first hole through printed circuit card at a predetermined location and having a first diameter predetermined to be sufficient to electrically isolate the preselected contact pad from all circuits contained in or on the printed circuit card. If any of the preselected contact pad or any conductor material directly attached to it remains attached to the first surface, it is delaminated, thereby separating it from the first surface of the printed circuit card. A preformed replacement conductor/contact pad structure is installed, such that one end of the structure having a replacement contact pad is positioned on the first surface of the printed circuit card at the location of the removed preselected contact pad. The second end of the replacement structure is electrically connected to at least one predetermined electronic component or layer, thereby completing the repair or modification.

### BACKGROUND OF THE INVENTION

1. Field of the Invention

The present invention generally relates to a method and structure for repair or making engineering changes to circuit boards having land grid array (LGA) pads. Specifically, a preformed replacement conductor/contact pad structure is installed following a drilling procedure to isolate the internal connections.

2. Description of the Related Art

Conventional systems have not addressed the specific problem solved in this invention. Surface pad replacement structures for surface mount solder application applications are currently available but none are available or identified for LGA application.

For example, Land Grid Array (LGA) technology, as shown in FIG. 1 as one example, allows for a higher density interconnection between a module 13 and a printed circuit board 10 without the need for a solder connection. The LGA electrical contact actuation uses a perpendicular compressive force 16. Since there is no contact wipe in this LGA technology, any existing oxide coating is not removed by horizontal motion. Therefore, the LGA contact pads on both the module and printed circuit board must be plated with a noble metal such as gold. A co-planar LGA surface on both the top and bottom of the circuit is necessary for a uniform load distribution.

Further, there arises a problem of making engineering changes or repairs to circuit boards with LGA pads, for example, a damaged LGA pad, an open internal net, a shorted internal net, or an erroneous net to be repaired on the circuit board surface. An LGA is typically used with an interposer 15 type connector having actuation only in the direction perpendicular to the board. A repair structure and method must be transparent to the LGA interposer interface. However, prior to the invention, no such structure and method have been known.

### SUMMARY OF THE INVENTION

In view of the foregoing and other problems, an object of the present invention is to provide a structure and method for making engineering changes or repairs to circuit boards having LGA pads.

It is another object of the present invention to provide a structure and method in which such circuit boards can be repaired or modified on the surface of the board.

It is yet another object of the invention to provide a repair structure and method that is low profile and transparent to the interposer interface, thereby not interfering with the LGA interposer.

It is yet another object of the invention to provide a method to repair high value raw cards or assembled cards with internal defects, thereby increasing yield. This aspect is particularly important for high value circuit boards with complex and dense wiring that have low yields, since they can now be routinely repaired or modified for engineering changes.

It is yet another object of the invention to provide a method in which internal wiring changes may be easily made to printed circuit cards containing LGAs, thereby reducing the debug cycle without new circuit design releases.

It is yet another object of the invention to provide a repair or modification process that can be executed in stages at various points in the manufacturing process.

The invention solves this problem by providing a replacement LGA pad/trace structure that will be equivalent to the structure and function of the original LGA pad.

In order to attain the above objects, according to one aspect of the invention, disclosed herein is a method to repair or modify a land grid array (LGA) interface mounted on a printed circuit board, where the land grid array interface having a plurality of contact pads on a first surface of the printed circuit board, where at least one of the contact pads is connected to at least one electronic component mounted in or on the printed circuit board by a conductor. The method includes, for a preselected one of the contact pads to be replaced, first drilling a first hole through the printed circuit board at a predetermined location and having a first diameter predetermined to be sufficient to electrically isolate the preselected contact pad from all circuits contained in or on the printed circuit board. If any of the preselected contact pad or any conductor material directly attached to it remains attached to the board surface, the remaining contact pad or other attached conductor material is delaminated, thereby separating it from the printed circuit board. A preformed replacement conductor/contact pad structure is installed. The structure has a first end serving as a replacement contact pad, which first end is positioned on the surface of the printed circuit board at the location of the removed preselected contact pad. The other end of the preformed replacement conductor/contact pad structure is then electrically connect to at least one predetermined electronic component or layer, thereby completing the repair or modification.

According to a second aspect of the invention, a replacement pad/trace structure for repair or modification of a printed circuit board containing at least one land grid array, each of the land grid arrays having a plurality of contact pads, is disclosed. The replacement structure includes a first contact pad portion having shape and dimensions to serve as a replacement contact pad for a predetermined contact pad to be replaced from one of the land grid arrays. A second trace portion serving as a conductive material is electrically connected to the first portion.

According to another aspect of the invention, also disclosed is a printed circuit board having one or more layers and having at least one land grid array (LGA) interface mounted thereon, where at least one plated through holes of the printed circuit board has been modified by drilling a hole having a diameter sufficient to electrically isolate a corresponding contact pad of the land grid array from all connected electronic components or structures.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a cross section view of a typical LGA printed circuit board;

FIG. 2a and FIG. 2b show two common array geometries for LGAs;

FIG. 3a and FIG. 3b show exemplary examples of the preformed structures for replacing the two array types shown in FIG. 2a and FIG. 2b;

FIG. 3c and FIG. 3d show the preformed structures following a replacement procedure described herein;

FIG. 4a shows one embodiment to complete the repair on the bottom surface using a single conductor insulated wire;

FIG. 4b shows another embodiment to complete the repair on the bottom using a pico-coax cable providing impedance matching and sheathing; and

FIG. 5 shows a cross section of a typical repaired contact pad including an insulator on the bottom surface.

### DETAILED DESCRIPTION OF A PREFERRED EMBODIMENT OF THE INVENTION

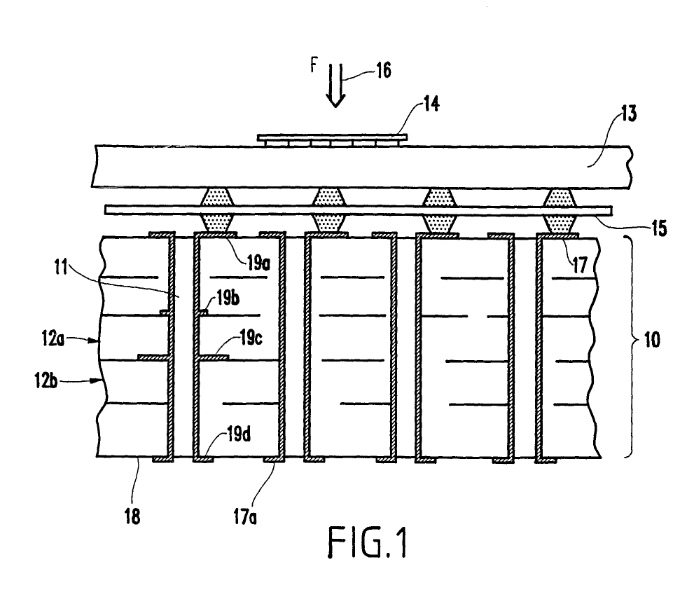

Referring now to the drawings, and more particularly to FIG. 1, a a cross section of a typical printed circuit board (PBC) 10 will be described in greater detail. Printed circuit board 10 is a multilayer board with internal signal wires, voltage and ground planes. The PBC 10 contains vias or plated through holes (PTH) 11 that permit connections between the different layers 12 (note as an example, that PTH 11 serves as a vertical interconnection for a circuit on layer 12a to circuit on layer 12b at 19b and 19c, as well as providing top surface interface 19a and bottom surface interface 19d). A module 13 with one or more integrated circuit chips 14 can be mounted to circuit board 10 using a Land Grid Array (LGA) interposer 15, thereby interconnecting circuit chip 14 to circuits on the circuit board. A compressive force 16 is applied to make the electrical contact between the module 13, the interposer 15, and the PCB 10 at contact pads 17. The bottom surface 18 of PCB 10 is the PCB surface opposing the LGA interface.

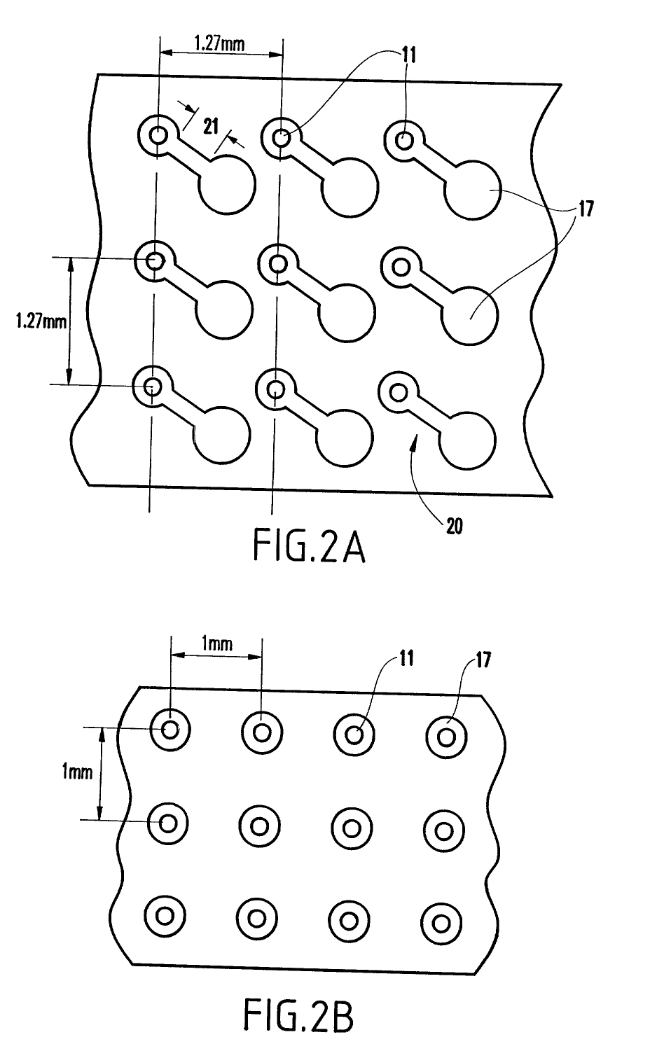

Referring now to FIG. 2a and 2b, in FIG. 2a the LGA pads 17 and through holes 11 on a standard 1.27-mm-pitch LGA array have a “dog bone pattern 20, and the contact pad 17 is offset from the through hole 11 by distance 21. In contrast, the “lily pad” LGA pads shown in FIG. 2b for a standard 1-mm-pitch LGA array have a PTH 11 centered in the LGA pad 17, and there is no offset corresponding to distance 21 shown in FIG. 2a. In both types, the LGA pads 17 are typically plated with a layer of gold plated over nickel in order to accommodate the lack of wipe in the LGA vertical compression technique.

In general, and referring back to FIG. 1, the repair of a LGA pad for either type of array requires that the internal connection to the pad first be deleted. This is accomplished in the invention by drilling out the metal interconnecting the various levels, for example shown at PTH 11. If the proper dimension drill is used, the metal of the PTH 11 is removed, thereby isolating the circuits on layers 12a and 12b. As would be well recognized in the art, care might be required to avoid an unintentional opening of the internal circuit on each layer 12a, 12b. Thus, in specific cases, it might be important to recognize that the drilling diameter would be chosen to ensure removal of the vertical metal interconnecting the various internal connections 19b, 19c, but not so large as to totally interrupt a critical conductor at, for example, 19b. A good rule of thumb is that the drilling diameter be 4 mils larger than the diameter of the through hole used for the PTH. Once the vertical metal of PTH 11 is drilled out, this drilling process disconnects all the internal connections for that target PTH.

The remaining portion of the target pad 19a, if any, is removed by a standard delamination method using a heated solder iron or a micro-chisel. A replacement pad and trace structure discussed below is then bonded to the surface of the circuit board 10. The repair structure must be reasonably co-planar to the other LGA pads such that the loading of the interposer is not affected.

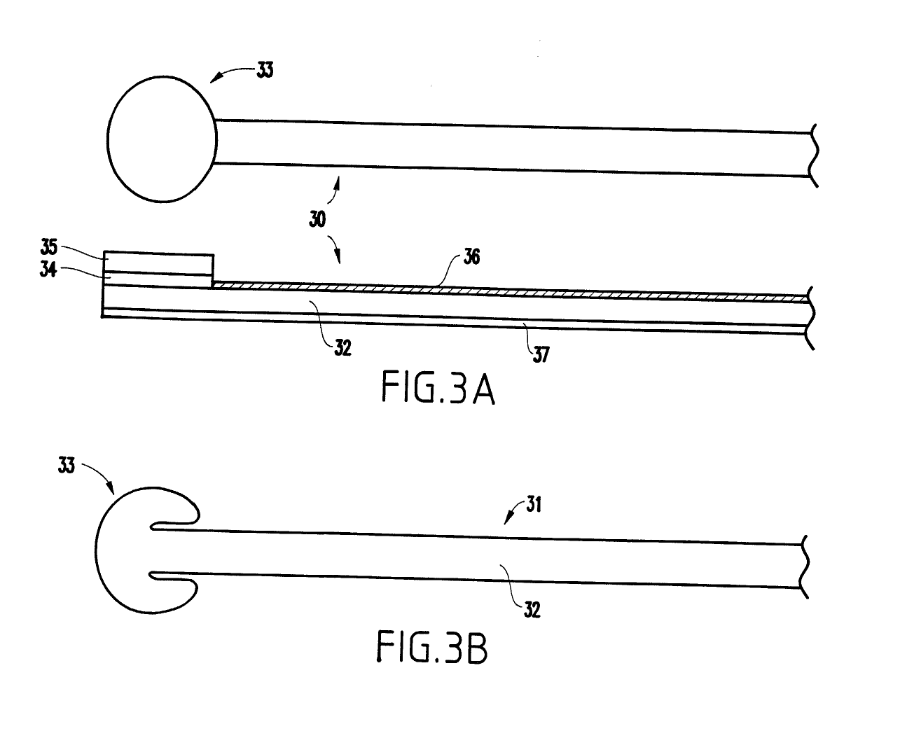

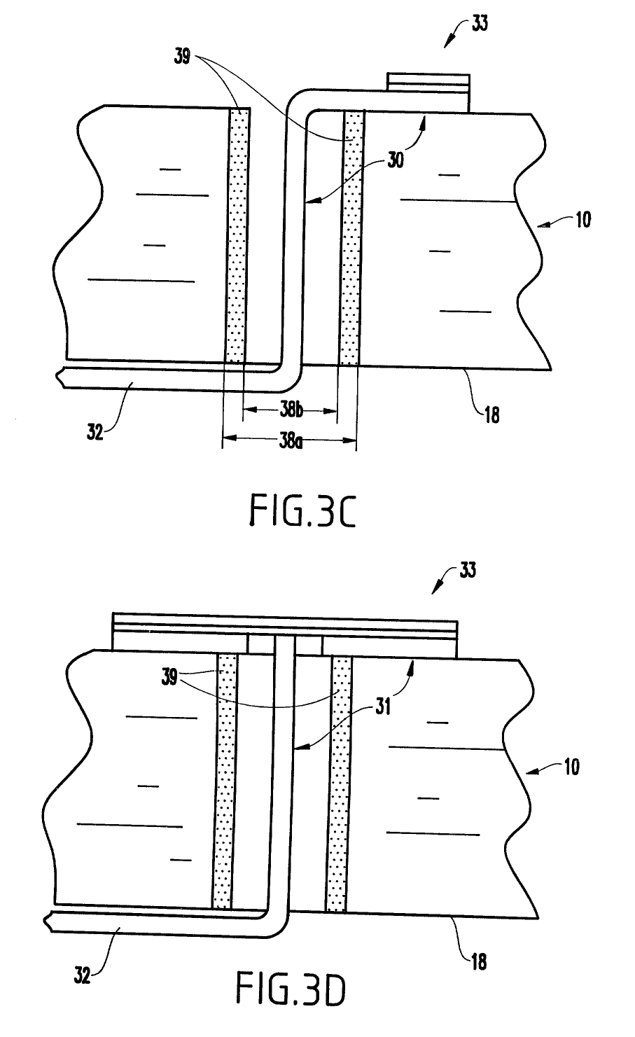

Referring now to FIGS. 3a-3d, a first embodiment of the present invention is described. A pad and trace structure 30 is shown in normal and cross section view in FIG. 3a for a “dog-bone” (1.27-mm pitch) LGA array repair. FIG. 3b shows the pad and trace structure 31 for a “lily-pad” (1-mm-pitch) LGA array repair. It should be obvious that the exact shape of this structure is not critical so long as it is shaped to perform the same function as the replaced contact pad and interface to the circuitry on the board. For example, the replacement pad need not be circular in shape, nor does the trace portion 32 necessarily need to be flat.

Both the 1.27-mm structure 30 and the 1-mm structure 31 are made from copper foil 32 and, in one embodiment, is selectively plated with nickel 34 and gold 35 on the pad 33 areas only, as shown. Alternatively, the entire trace 32 may also be plated with nickel and gold. An insulating coating 36 may also be applied to the plated or unplated copper trace. Another plating option may be a thick gold plating of more than 200 microinches over the copper foil with no nickel plating. Since nickel is more brittle than copper, if the entire trace is plated with nickel, the plating method and thickness of the nickel must be controlled such that the resulting trace structure will flex 90 degrees multiple times without any cracks in the plating or the underlying copper foil. If the thick gold plating alone is used over the copper foil, it will provide a flexible structure without the need of a nickel diffusion barrier. Thus, the surface may be plated with only thick gold plating to allow a more robust flexible structure.

In a preferred embodiment, the bottom surface of the unplated copper foil 32 is coated with a heat activated adhesive 37.

A preferred thickness of the copper foil 32 is 1.4 mils, a preferred thickness of the nickel plating 34 is 50 microinches, and a preferred thickness of the gold plating 35 is 30 microinches. The pad trace structure can be manufactured using a straight forward photoresist chemical etch process well known in the art.

As mentioned above, the structure may alternatively have a thick gold layer plated over the copper foil, an embodiment that does not require the additional nickel diffusion barrier. A preferred thickness of the thick gold plating is 200 microinches. This structure without the nickel plating more robustly allows the trace to be bent at 90 degrees repeatedly without cracking the trace.

As another alternative embodiment for contact pads involving critical signals, the structure may also be built up to form of an impedance-controlled structure having a ground plane, in effect a structure similar to a coax cable. In this embodiment, the copper foil trace would be coated with a dielectric over the trace portion, and then a subsequent outer conductor layer serving as a ground plane would be deposited on top of the dielectric coating.

FIG. 3c shows a cross section view of a repair for a site on a 1.27-mm array, and FIG. 3d shows a corresponding view of a 1-mm array site. A hole of a first diameter 38a has been drilled, where the diameter was predetermined to be sufficient to sever all internal connections by removing at least all of the vertical interconnecting metal. As mentioned above, a typical value for this first diameter is 4 mils greater than the through hole diameter. This hole was then filled with an epoxy 39 and a smaller diameter hole 38b then drilled through the epoxy. If required, any remaining metal of the original contact pad was also removed by a delamination process. The appropriate structure 30 or 31 was then installed by threading the trace portion 32 through the hole 38b so that the contact pad 33 assumes the location of the pad 17 selected for replacement.

FIG. 3c shows that the hole will typically be drilled at an offset distance from the contact pad 17 for the 1.27-mm array but that no offset is involved for the array in FIG. 3d since the initial drill hole will penetrate through the contact pad 17 of the 1-mm array. The hole may be drilled from either the top or bottom side. In a typical mass production facility, the drilling would be automated and the drilling coordinates of the hole would be part of the circuit board design data. This data may be loaded to an auto drill tool that is industry standard. The replacement structure 30, 31 may optionally have an adhesive holding the contact pad in place but this in not absolutely necessary. Also, it is easy to see that the filling using a dielectric epoxy and the second drilling at a smaller diameter hole could be considered optional if the trace passing through the hole had a sufficient outer insulation layer.

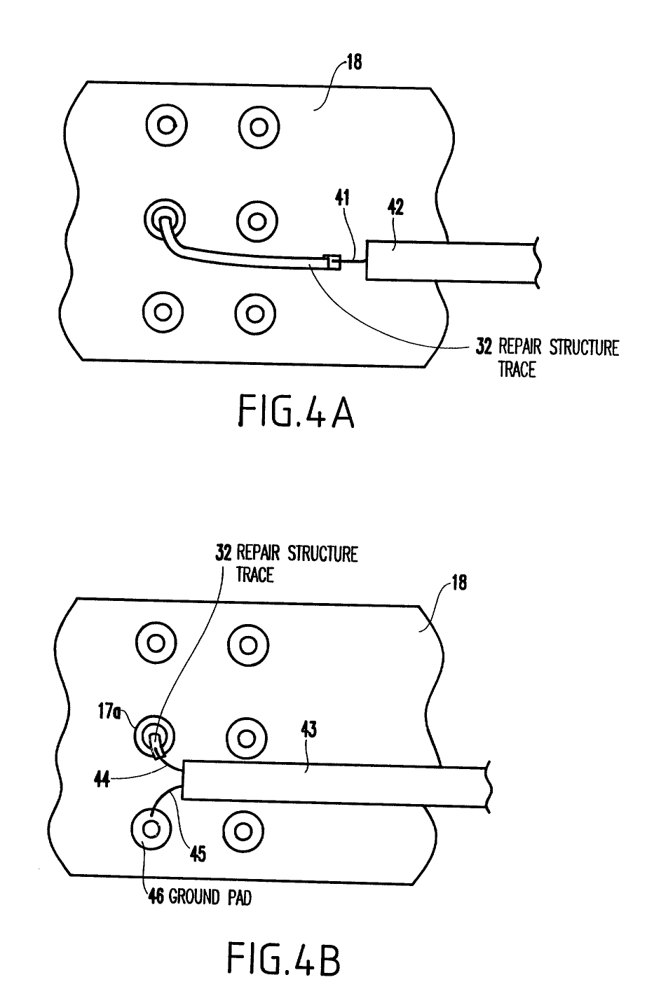

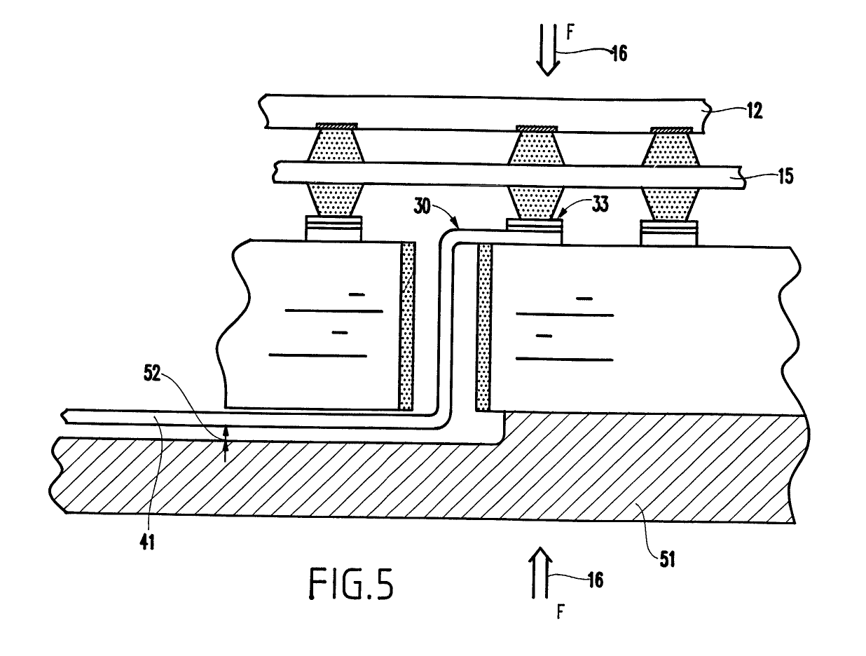

A number of possibilities to complete the repair should be obvious to one of ordinary skill in the art. For example, depending on specific details of the intended repair or modification, the trace 32 shown in FIG. 3c or FIG. 3d protruding through the bottom surface 18 of the PCB 10 could be simply soldered to one of the PTH bottom surface pads 17a (see item17a on FIG. 1). FIG. 4a and 4b demonstrate two other exemplary wiring methods to complete the repair using the copper trace portion 32 of structure 30 or 31 on the bottom side 18 of the PCB.

A single conductor wire 41 having insulator coating 42 is shown in FIG. 4a. The other end of the single wire 41 is not shown in the figure but would be variously connected to either another LGA repair structure, connector pin, or may even have a resistor in series with the wire before termination, in order to adjust timing delay for the signal. Depending on circuit board details, the repair with the single wire might use one of the “junction pads” for making the solder connection between the repair trace 32 and the wire conductor 41. A number of these junction pads are typically incorporated in printed board design for possible future repairs.

The signal wire 44 of the pico-coax 43 in FIG. 4b is shown bonded directly to the repair structure trace 32 and using the remnant of the lower surface PTH pad 17a (see also item 17a in FIG. 1) left in place from the drilling steps. This “stacked” connection in which the repair trace 32, the coax signal wire 44, and the lower-surface PTH pad 17a are all soldered in a stack would be a preferable connection technique in “lily pad” arrays. The coax ground wire 45 is shown bonded to an adjacent bottom surface PTH pad 46 that happens to serve as a ground pad for the adjacent critical signal. This adjacent ground pad configuration would be typical for grid arrays having critical signals requiring a coax environment.

FIG. 5 shows a cross section of the final assembly of a repair. LGA module 12 is mounted to the repaired LGA site using contact actuation of the LGA interposer 15 by compressive force 16. The preformed repair structure 30 has been mounted so that replacement pad 33 occupies the area of the removed contact pad. A custom milled insulator 51 has been fabricated to protect the single conductor wire 41 to provide clearance 52 around the wire 41. Wiring repairs done outside of the LGA area would not require a custom milled insulator 51. The protective insulator 51 may be made of various materials but a preferred material is FR4 resin. The insulator 51 is required as protection against the interposer actuation compression action and is typically held in place by compression of the interposer actuation hardware.

The final step in the repair process would be a procedure to clean the replacement contact pad 33 with a cleaner such as xylene. Xylene has been shown to adequately remove any silicone based adhesive from the gold plated pads. The cleaning process involves using a lint free cloth soak with xylene to wipe the gold pad in order to prepare the pad surface for the non-wiping contact used in LGA technology. There are three chemical forms (isomers) of Xylene: otho-xylene, meta-xylene, and para-xylene. Commercial xylene, generally referred to as xylene (mixed isomers) or technical xylene, is a mixture of widely varying proportions of these three isomers (with m-xylene predominating), together with ethylbenzene (6-20%) and smaller amounts of toluene, trimethylbenzene, phenol, thiophene, pyridine and non-aromatic hydrocarbons.

As another alternative embodiment, the LGA pad trace repair structure may be completed on the top surface of the card, rather than the bottom surface. This would be done on LGA arrays that have enough clearance between contact pads to allow the trace to be routed without creating an electrical short between the pads. The advantage of this method is that no custom milled insulator plate is needed.

This invention benefits both the raw board fabricator and board assembly houses. For example, a raw board fabricator can pre-drill all the LGA pads that require repair for either mechanical damage or internal wiring changes, leaving it to the board assembly house to later provide the final repair process.

This repair methodology for LGA pads may be extended to all surface mount or LGA components that required repair or engineering changes. This will enable high value circuit boards with complex and dense wiring that have low yields to be repaired.

While the invention has been described in terms of a single preferred embodiment, those skilled in the art will recognize that the invention can be practiced with modification within the spirit and scope of the appended claims.

Having thus described our invention, what we claim as new and desire to secure by letters patent is as follows:

1. A method to repair or modify a land grid array (LGA) interface mounted on a printed circuit board, said land grid array interface comprising a plurality of contact pads on a first surface of said printed circuit board, wherein at least one of said contact pads is connected to at least one electronic component mounted in or on said printed circuit board by a conductor, said method comprising:
for a preselected one of said contact pads to be replaced, drilling a first hole through said printed circuit board at a predetermined location and having a first diameter predetermined to be sufficient to electrically isolate said preselected contact pad from all circuits contained in or on said printed circuit board;
if any of said preselected contact pad or any conductor material directly attached to said preselected contact pad remains attached to said first surface, delaminating said remaining contact pad and any remaining attached conductor material, thereby separating said remaining contact pad and any remaining attached conductor material from said first surface of said printed circuit board;
installing a preformed replacement conductor/contact pad structure such that a first end of said structure comprising a replacement contact pad is positioned on said first surface of said printed circuit board at the location of said removed preselected contact pad; and
electrically connecting a second end of said preformed replacement structure comprising a replacement conductor to at least one predetermined electronic component or layer, thereby completing said repair or modification.

2. The method of claim 1, further comprising:
filling said first drilled hole with a dielectric epoxy.

3. The method of claim 2, further comprising:
drilling a second hole of a predetermined diameter smaller than said first diameter through said dielectric epoxy.

4. The method of claim 3, further comprising:
threading said trace end of said preformed replacement conductor/contact pad structure through said second hole.

5. The method of claim 1, further comprising:
affixing at least a portion of said replacement structure to a surface of said printed circuit board.

6. The method of claim 5, wherein said affixing comprises activating a heat activated adhesive.

7. The method of claim 1, further comprising:
filling said hole with an insulating material;
drilling a second hole having a second diameter smaller than said first diameter; and
said installing of said preformed replacement conductor/contact pad structure comprises inserting through said second hole said second termination of said structure such that said first termination of said structure having a replacement contact pad is positioned on said first surface of said printed circuit board at the location of said delaminated contact pad.

8. The method of claim 1, further comprising protecting at least a portion of said replacement conductor by an insulating material.

9. The method of claim 1, further comprising cleaning a contact surface of said replacement contact pad.

10. A replacement pad/trace structure for repair or modification of a printed circuit board containing at least one land grid array, each said land grid array comprising a plurality of contact pads, said replacement pad/trace structure comprising:
a first contact pad portion having shape and dimensions to serve as a replacement contact pad for a predetermined contact pad to be replaced from one of said land grid arrays; and
a second trace portion comprising a conductive material electrically connected to said first portion.

11. The replacement structure of claim 10, wherein said first contact pad portion and said second trace portion comprises copper foil.

12. The replacement structure of claim 10, wherein at least a portion of a bottom surface of said first contact pad portion and said second trace portion is coated with a heat activated adhesive.

13. The replacement structure of claim 10, wherein at least a portion of said first contact pad portion and said second trace portion is plated with gold.

14. The replacement structure of claim 13, wherein said portion plated with gold is confined to said contact pad portion.

15. The replacement structure of claim 13, wherein said portion plated with gold is additionally plated with nickel.

16. The replacement structure of claim 10, further comprising:
an outer insulating layer on at least a portion of said second trace portion.

17. The replacement structure of claim 16, further comprising:
a conductive layer on the outer surface of said insulating layer.

18. The replacement structure of claim 17, further comprising:
an outer insulating layer on the outer surface of said conductive layer.

19. A printed circuit board comprising:
one or more layers; and
and at least one land grid array (LGA) interface mounted thereon, said land grid array interface comprising a plurality of contact pads on a first surface of said printed circuit board, wherein at least one of said contact pads is connected by a conductor to at least one electronic component or structure mounted in or on at least one of said layers by a plated through hole, and wherein at least one of said plated through holes has been modified by drilling a hole having a diameter sufficient to electrically isolate a corresponding one of said contact pads from said connected electronic component or structure.
